(19) United States
(12) Patent Application Publication
(10) Pub. No.: US 2024/0318313 A1
(43) Pub. Date: Sep. 26, 2024

(54) GAS BAFFLE AND SUBSTRATE PROCESSING APPARATUS

(71) Applicant: TES CO., LTD, Yongin-si (KR)

(72) Inventor: Dae-Geun YOON, Yongin-si (KR)

(73) Assignee: TES CO., LTD, Yongin-si (KR)

(21) Appl. No.: 18/608,937

(22) Filed: Mar. 19, 2024

(30) Foreign Application Priority Data
Mar. 23, 2023 (KR) 10-2023-0037759

(51) Int. Cl. C23C 16/455

(52) U.S. Cl. CPC C23C 16/45591; C23C 16/45565

(57) ABSTRACT

Provided is a gas baffle, more particularly, a gas baffle for effectively dispersing gas before supplying gas to a substrate through a showerhead in a substrate processing apparatus.

### CROSS-REFERENCE TO RELATED APPLICATION

This application is based on and claims priority under 35 U.S.C. § 119 to Korean Patent Application No. 10-2023-0037759, filed on Mar. 23, 2023, in the Korean Intellectual Property Office, the disclosure of which is incorporated by reference herein in its entirety.

### TECHNICAL FIELD

The present disclosure relates to a gas baffle and a substrate processing apparatus, and more particularly, to a gas baffle and a substrate processing apparatus, for effectively dispersing gas before supplying gas to a substrate through a showerhead in a substrate processing apparatus.

### BACKGROUND

In general, a substrate processing apparatus accommodates a substrate in a chamber and supplies a process gas to the substrate through a showerhead to perform various processing processes. In this case, it is necessary to uniformly disperse and diffuse the process gas and supply the process gas to the substrate.

FIGS. 5A and 5B illustrate a gas baffle 20 for dispersing process gases in a substrate processing apparatus according to the related art. FIG. 5A illustrates the gas baffle 20 provided in a lid 25. FIG. 5B is a perspective view of the gas baffle 20 viewed from the below.

Referring to FIGS. 5A and 5B, gas supply lines 21A and 21B is formed in the lid 25, and the gas baffle 20 is installed below the gas supply lines 21A and 21B. In this case, a recess 23 that communicates with the gas supply lines 21A and 21B may be formed on a lower surface of the lid 25, and the gas baffle 20 may be installed below the recess 23. The gas baffle 20 may be installed apart from the lower surface of the lid 25 by bolts 24 passing through coupling holes 22.

Thus, in the gas baffle 20 according to the related art shown in FIGS. 5A and 5B, the process gas supplied through the gas supply lines 21A and 21B may be dispersed through a space between the lid 25 and a showerhead 30 by bending a flow channel by the gas baffle 20.

However, in the structure shown in FIGS. 5A and 5B, the process gas is not smoothly dispersed to the showerhead 30 directly below the gas baffle 20, and thus a so-called dead zone may be generated.

FIGS. 6A and 6B illustrate a gas baffle 60 for dispersing a process gas in another substrate processing apparatus according to the related art. FIG. 6A illustrates the gas baffle 60 provided in a lid 50. FIG. 6B is a perspective view of the gas baffle 60 viewed from the below.

Referring to FIGS. 6A and 6B, gas supply lines 41A and 41B is formed in the lid 50, and the gas baffle 60 is installed below the gas supply lines 41A and 41B. In this case, a recess 52 that communicates with the gas supply lines 41A and 41B may be formed on a lower surface of the lid 50, and the gas baffle 60 may be installed below the recess 52. The gas baffle 60 may be installed on a lower surface of the lid 50 by bolts 80 passing through coupling holes 66.

An opening 64 extending in a circumferential direction is formed in the gas baffle 60, and a protrusion 62 protruding toward the recess 52 described above may be formed in a central portion.

Therefore, the process gas supplied through the gas supply lines 41A and 41B may be dispersed through the opening 64 of the gas baffle 60 via a space between the lid 50 and a showerhead 70 while being dispersed by the protrusion 62.

However, even in the structure shown in FIGS. 6A and 6B, the process gas is not smoothly dispersed to the showerhead 70 directly below the gas baffle 60, and thus it is difficult to prevent a dead zone.

### SUMMARY

To overcome the above problem, an object of the present disclosure is to provide a gas baffle and a substrate processing apparatus, for preventing a dead zone by effectively dispersing gas before supplying gas to a substrate through a showerhead.

According to an aspect of the present disclosure, a gas baffle provided below a gas supply line formed in a chamber in which a processing process is performed on a substrate includes a baffle plate configured to disperse a process gas supplied from the gas supply line, and a plurality of openings extending radially from a central portion of the baffle plate toward an edge portion of the baffle plate to pass the process gas, inclined to the baffle plate and inclined along a circumferential direction of the baffle plate to disperse the process gas.

The plurality of openings may be inclined at a predetermined angle to the baffle plate.

The plurality of openings may extend in a straight line from the central portion of the baffle plate toward the edge portion of the baffle plate.

The baffle plate may include a first surface facing the gas supply line, and a second surface located on an opposite side of the first surface, and a protrusion may be further formed on a central portion of the first surface.

A through hole may be formed in the protrusion, and the gas baffle may further include a guide configured to guide a flow of gas inside the through hole.

According to another aspect of the present disclosure, a substrate processing apparatus includes a chamber including a chamber body with an open top providing a processing space for a substrate, and a lid configured to seal the open top of the chamber body, a showerhead provided above the processing space and configured to supply the process gas to the substrate, and a gas baffle formed in the chamber and provided below a gas supply line configured to supply a process gas to the substrate to disperse the process gas, wherein the gas baffle includes a baffle plate, and a plurality of openings extending radially from a central portion of the baffle plate toward an edge portion of the baffle plate to pass the process gas, inclined to the baffle plate and inclined along a circumferential direction of the baffle plate to disperse the process gas, and the plurality of openings are inclined at a predetermined angle to the baffle plate.

The gas supply line may be formed in the lid, and the gas baffle may be provided between the lid and the showerhead below the gas supply line.

The baffle plate may include a first surface facing the gas supply line, and a second surface located on an opposite side of the first surface, and a protrusion may be further formed on a central portion of the first surface.

### BRIEF DESCRIPTION OF THE DRAWINGS

Embodiments will be more clearly understood from the following detailed description taken in conjunction with the accompanying drawings in which:

FIG. 1 is a side cross-sectional view showing a chamber of a substrate processing apparatus including a gas baffle according to an embodiment of the present disclosure;

FIG. 2 is a perspective view of a gas baffle according to an embodiment of the present disclosure;

FIG. 3 is a cross-sectional perspective view showing a state in which a gas baffle is connected to a lid;

FIG. 4 is a side cross-sectional view showing one opening from among a plurality of openings; and

FIGS. 5A through 6B are diagrams showing a gas baffle according to the related art.

### DETAILED DESCRIPTION OF THE EMBODIMENTS

Hereinafter, a structure of a gas baffle in a substrate processing apparatus according to an embodiment of the present disclosure will be described in detail with reference to the drawings.

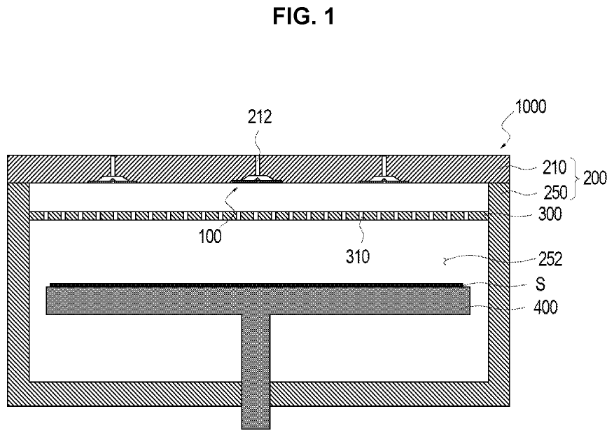

FIG. 1 is a side cross-sectional view showing a chamber 200 of a substrate processing apparatus 1000 including a gas baffle 100 according to an embodiment of the present disclosure.

Referring to FIG. 1, the substrate processing apparatus 1000 may include the chamber 200 including a chamber body 250 with an open top that provides a processing space 252 for a substrate S and a lid 210 that seals the open top of the chamber body 250, a showerhead 300 provided above the processing space 252 to supply a process gas to the substrate S, and the gas baffle 100 formed in the chamber 200 formed in the chamber 200 and provided below a gas supply line 212 supplying a process gas to the substrate S to disperse the process gas.

The chamber body 250 may have an open top, and a substrate support 400 on which the substrate S is accommodated may be located inside the chamber body 250. The open top of the chamber body 250 may be sealed by the lid 210.

The showerhead 300 including a plurality of supply holes 310 formed therein through a process gas is supplied to the substrate S may be provided above the processing space 252.

The gas supply line 212 may be formed in the chamber 200 to supply a process gas to the substrate S.

The gas supply line 212 may be formed in the lid 210 as shown in the drawing, but is not limited thereto. In other words, the lid 210 described here is an example, and the gas supply line 212 may also be formed in the chamber body 250, and an object on which the gas baffle 100 is installed is not limited to the lid 210. Hereinafter, in this specification, for convenience of explanation, the gas baffle 100 will be described as being provided below the lid 210.

One gas baffle 100 may be installed on the lid 210, but may also be provided in plural as shown in the drawing. When a cross-sectional area or size of the chamber 200 is large, the gas baffle 100 may be configured in plural to disperse and diffuse the process gas.

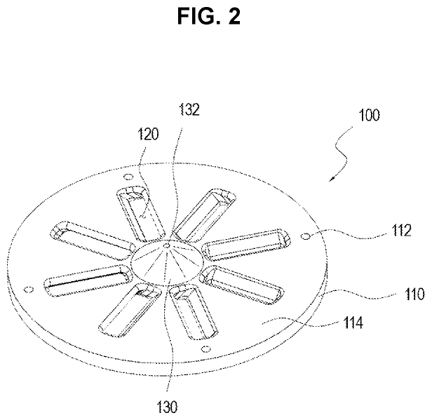

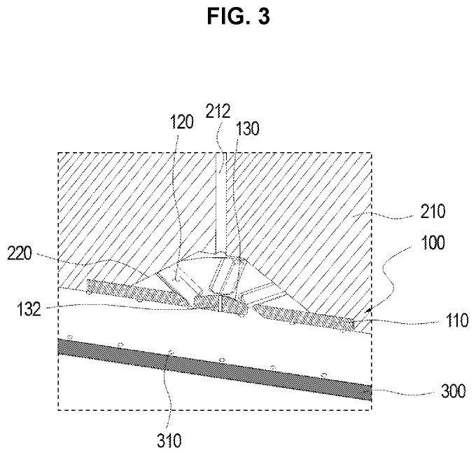

FIG. 2 is a perspective view of the gas baffle 100 according to an embodiment of the present disclosure. FIG. 3 is a cross-sectional perspective view showing a state in which the gas baffle 100 is connected to the lid 210.

Referring to FIGS. 2 and 3, the gas baffle 100 may be provided below the gas supply line 212 formed in the chamber 200 in which a processing process is performed on the substrate S.

For example, the gas supply line 212 may be formed in the lid 210, and the gas baffle 100 may be provided between the lid 210 and the showerhead 300 below the gas supply line 212. In more detail, the gas baffle 100 may be provided on a lower surface of the lid 210.

The gas baffle 100 may include a baffle plate 110 dispersing a process gas supplied from the gas supply line 212, and a plurality of openings 120 that extends radially from a central portion of the baffle plate 110 toward an edge portion of the baffle plate to pass the process gas and are inclined to the baffle plate 110 and are inclined along a circumferential direction of the baffle plate 110 to disperse the process gas.

The baffle plate 110 may have a circular shape in plan and a predefined thickness. This circular shape is shown as an example and may be modified into various forms.

The thickness of the baffle plate 110 may be predefined, and for example, may have a thickness of about 10 mm to 20 mm. The thickness of the baffle plate 110 is described as an example, and may be appropriately adjusted according to various environmental conditions such as a process condition for a substrate, a type of a process gas, and a flow rate and velocity of the process gas.

A coupling hole 112 for installing the baffle plate 110 may be formed at an edge of the baffle plate 110. The baffle plate 110 may be installed on the lid 210 by connecting a coupling member (not shown) such as a bolt through the coupling hole 112 to an object such as the lid 210. In this case, a recess 220 concavely formed upward may be formed on a lower surface of the lid 210, and the gas supply line 212 described above may be formed in the recess 220. That is, the recess 220 may be formed at a lower end of the gas supply line 212, and the baffle plate 110 described above may be connected to the recess 220.

The plurality of openings 120 may be formed in the baffle plate 110. The process gas supplied through the gas supply line 212 may pass through the opening 120 and be uniformly dispersed below the baffle plate 110.

In this case, the opening 120 may be formed to extend radially from the central portion of the baffle plate 110 toward the edge portion. In addition, the plurality of openings 120 may extend in a straight line from the central portion of the baffle plate 110 toward the edge portion of the baffle plate 110. In FIG. 2, eight openings 120 are described, but this is only an example, and the number of openings 120 may be appropriately adjusted in consideration of the size of the baffle plate 110, and the like.

The opening 120 may have a constant width in the form of a slit extending from the central portion of the baffle plate 110 toward the edge portion. However, although not shown, it may be possible to vary the width of some of the plurality of openings 120.

The opening 120 may be inclined along a circumferential direction of the baffle plate 110.

That is, the opening 120 may be inclined along the circumferential direction rather than a radial direction with respect to the baffle plate 110.

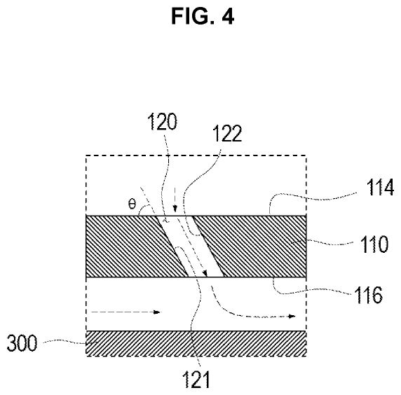

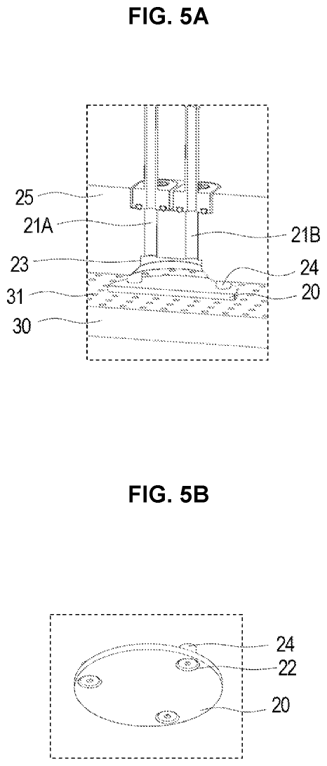

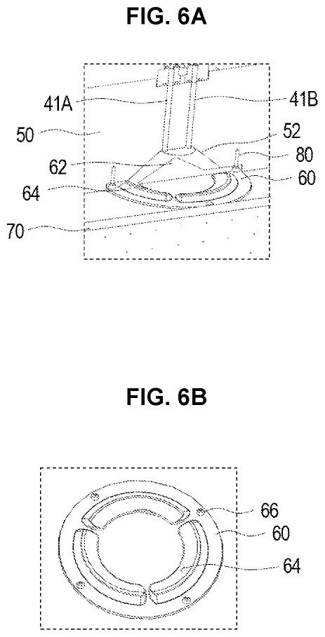

FIG. 4 is a side cross-sectional view showing one opening 120 from among the plurality of openings 120 described above.

Referring to FIGS. 2 to 4, the openings 120 may be inclined at a predefined angle θ along a circumferential direction of the baffle plate 110.

In this case, a pair of sidewalls 121 and 122 defining the opening 120 may be inclined at the predefined angle θ as shown in FIG. 4.

Accordingly, the process gas supplied from an upper portion of the baffle plate 110 may be dispersed and diffused in a space between the showerhead 300 and the baffle plate 110 while passing through the inclined opening 120. In FIG. 4, a flow of the process gas is shown by a hidden arrow.

When the process gas passes through the opening 120 of the baffle plate 110, the process gas may be more effectively dispersed into a space between the showerhead 300 and the baffle plate 110 due to the inclination of the opening 120.

The baffle plate 110 may include a first surface 114 facing the gas supply line 212 and a second surface 116 located on an opposite side of the first surface 114. In this case, the second surface 116 may face the showerhead 300 described above.

In the above-described configuration, a protrusion 130 may be formed in a central portion of the first surface 114 of the baffle plate 110. The protrusion 130 may be widened in cross-sectional area, diameter, or size from the top toward the baffle plate 110 at the bottom. For example, the protrusion 130 is shown in a shape of a roughly cone in FIG. 2, but is not limited to this, and may also be formed in a shape of a cone or a polygonal pyramid such as a triangular pyramid or square pyramid.

The process gas supplied from the gas supply line 212 may be uniformly distributed radially from the central portion of the baffle plate 110 by the protrusion 130 and directed toward the opening 120 by the above-described configuration of the protrusion 130.

In the above-described configuration, a so-called dead zone in which the process gas is not supplied may be generated in a space between the showerhead 300 and a lower portion of a central portion of the baffle plate 110.

To prevent this, a through hole 132 may be formed in the protrusion 130 described above. Thus, a portion of the process gas supplied through the gas supply line 212 may be supplied to the lower portion of the central portion of the baffle plate 110 through the through hole 132 to prevent the above-described dead zone. The remaining process gases may be dispersed along the protrusion 130 and dispersed below the baffle plate 110 through the opening 120.

In this case, a guide (not shown) guiding a flow of the gas may be formed inside the through hole 132.

For example, the guide may be configured in the form of a screw thread formed on an inner wall of the through hole 132. Therefore, when the process gas passes through the through hole 132, the process gas may be swirled like a whirlwind or a whirlpool by the guide, and thus the process gas may disperse and diffuse more effectively below the through hole 132.

According to the present disclosure having the above-described configuration, a dead zone may be prevented by effectively dispersing the gas before supplying the gas to the substrate through the showerhead in the substrate processing apparatus.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A gas baffle provided below a gas supply line formed in a chamber in which a process is performed on a substrate, the gas baffle comprising:
a baffle plate configured to disperse a process gas supplied from the gas supply line; and
a plurality of openings extending radially from a central portion of the baffle plate toward an edge portion of the baffle plate to pass the process gas, inclined to the baffle plate and inclined along a circumferential direction of the baffle plate to disperse the process gas.

2. The gas baffle of claim 1, wherein the plurality of openings are inclined at a predetermined angle to the baffle plate.

3. The gas baffle of claim 1, wherein the plurality of openings extend in a straight line from the central portion of the baffle plate toward the edge portion of the baffle plate.

4. The gas baffle of claim 1, wherein the baffle plate includes a first surface facing the gas supply line, and a second surface located on an opposite side of the first surface, and
a protrusion is further formed on a central portion of the first surface.

5. The gas baffle of claim 4, wherein a through hole is formed in the protrusion.

6. The gas baffle of claim 5, further comprising a guide configured to guide a flow of gas inside the through hole.

7. A substrate processing apparatus comprising:
a chamber including a chamber body with an open top providing a processing space for a substrate, and a lid configured to seal the open top of the chamber body;
a showerhead provided in the processing space and configured to supply the process gas to the substrate; and
a gas baffle formed in the chamber and provided below a gas supply line configured to supply a process gas to the substrate to disperse the process gas,
wherein the gas baffle includes a baffle plate, and a plurality of openings extending radially from a central portion of the baffle plate toward an edge portion of the baffle plate to pass the process gas, inclined to the baffle plate and inclined along a circumferential direction of the baffle plate to disperse the process gas, and the plurality of openings are inclined at a predetermined angle to the baffle plate.

8. The substrate processing apparatus of claim 7, wherein the gas supply line is formed in the lid, and
the gas baffle is provided between the lid and the showerhead below the gas supply line.

9. The substrate processing apparatus of claim 8, wherein the baffle plate includes a first surface facing the gas supply line, and a second surface located on an opposite side of the first surface, and
a protrusion is further formed on a central portion of the first surface.
